(19) United States
(12) Patent Application Publication
(10) Pub. No.: US 2023/0420322 A1
(43) Pub. Date: Dec. 28, 2023

(54) ORGANIC ADHESION PROMOTOR FOR DIELECTRIC ADHESION TO A COPPER TRACE

(71) Applicant: Intel Corporation, Santa Clara, CA (US)

(72) Inventors: Yi YANG, Gilbert, AZ (US); Srinivas V. PIETAMBARAM, Chandler, AZ (US); Suddhasattwa NAD, Chandler, AZ (US); Darko GRUJICIC, Chandler, AZ (US); Marcel WALL, Phoenix, AZ (US)

(21) Appl. No.: 17/848,615

(22) Filed: Jun. 24, 2022

(51) Int. Cl. H01L 23/31; H01L 23/498; H01L 23/495

(52) U.S. Cl. CPC H01L 23/3142; H01L 23/49827; H01L 23/49513

(57) ABSTRACT

Embodiments herein relate to systems, apparatuses, or processes directed to an organic adhesion promoter layer on the surface of a copper trace to reduce delamination between a dielectric material and the surface of the copper trace, and to facilitate a smooth surface interface between the surface of the copper trace and of a copper feature, such as a copper-filled via, placed on the surface of the copper trace. The smooth surface interface reduces insertion loss and enables routing of higher frequency signals on a package, and does not require roughing of the copper trace in order to adhere to the dielectric material. Other embodiments may be described and/or claimed.

### FIELD

Embodiments of the present disclosure generally relate to the field of package assemblies, and in particular package assemblies that include high-speed input/output (HSIO) traces.

### BACKGROUND

Continued reduction in end product size of mobile electronic devices such as smart phones and ultrabooks is a driving force for the development of reduced size system in package components. As speed requirements between dies on a package, for example between a compute die and a memory die, continues to increase, density of traces in a package substrate will continue to increase, and the increased frequency and speed of transmission on these traces will become increasingly important.

### BRIEF DESCRIPTION OF THE DRAWINGS

FIGS. 1A-1B illustrate cross section side views of a legacy copper trace with a roughened surface within a substrate and a copper trace with an organic adhesion promoter (OAP) partially surrounding a copper trace within a substrate, in accordance with various embodiments.

FIG. 2 is a photo of a cross section of a copper trace with an OAP partially surrounding the copper trace with a copper via electrically coupled with the copper trace, in accordance with various embodiments.

FIGS. 3A-3F illustrate cross section side views of stages in a manufacturing process for creating a legacy substrate that includes copper traces with a roughened surface that are coupled with copper vias.

FIGS. 4A-4F illustrate cross section side views of stages in a manufacturing process for creating a substrate that includes copper traces with an OAP partially surrounding the copper traces that are coupled with a copper via, accordance with various embodiments.

FIG. 5 illustrates an example process for creating a copper trace that is partially surrounded with an OAP and coupled with a copper via, in accordance with various embodiments.

FIG. 6 schematically illustrates a computing device, in accordance with various embodiments.

### DETAILED DESCRIPTION

Embodiments of the present disclosure may generally relate to systems, apparatus, and/or processes directed to creating a package that includes transmission lines that operate at high frequencies, where the transmission lines include copper interfaces. In embodiments, smooth surfaces for the interface between where a copper trace and a copper via are directly electrically coupled will reduce electrical resistance between the surfaces. In embodiments, the smooth surfaces may facilitate maintaining an insertion loss budget for the package.

To promote mechanical stability of the package where the smooth copper surfaces come into contact with a dielectric, to promote adhesion with the dielectric the copper surfaces may be coated with an OAP film prior to the application of the dielectric to the copper surface. As a result, the likelihood of delamination of the dielectric from the copper surface is reduced. In embodiments, the OAP may provide a chemical adhesive layer to enable a smooth copper/dielectric interface without compromising the adhesion between metal and organic dielectric layers. In embodiments, OAP on copper surfaces may be removed prior to forming a copper feature, such as a metal via, when creating a direct electrical connection on the copper surface. Although copper is specifically mentioned, embodiments described herein may be applied to any conductive metal.

Embodiments described herein may use a semi-additive process (SAP) when using OAP film as an adhesion promoter that uses a dry desmear process to prevent the copper-OAP-dielectric interface from delaminating during fabrication. This may be referred to as a semi-wet SAP process flow that enables a wet OAP process with compatibility with dry desmear and sputter seed deposition processes. If wet desmear chemicals are used, for example a permanganate solution, delamination may result. As a result, in embodiments, a sputtered seed process may be preferred together with a dry desmear process to provide a wet-chemical free process flow to maintain the copper-OAP-dielectric interface integrity. This is in contrast to using an inorganic adhesion promotor using a dry SAP flow, for example using SiNx with dry etching and a sputter seed process, which is less cost-effective.

Embodiments described herein may improve the performance of transmission lines within packages by enabling them to operate at higher frequencies while maintaining a package insert loss budget by forming copper connections with smooth copper surfaces to reduce insertion loss and to improve overall package mechanical stability.

In legacy implementations, smooth copper surfaces that are used during manufacture, for example during substrate manufacture, may cause weak bonding between a dielectric, for example an organic dielectric that is laminated or otherwise placed on the copper surface. This weak bonding may result in delamination, which may result in the failure of the package. In legacy implementations, adhesion between dielectric and copper surfaces has been increased by roughening the copper surface to provide an anchor to which the laminated dielectric may mechanically adhere. However, in these legacy implementations, the roughened surface of the copper results in a higher insertion loss for higher frequencies of the signal being transmitted, as compared to smooth surfaces of copper.

In a first group of implementations, a non-roughening dielectric adhesion promotion solution for copper surfaces has used organic adhesion promoters that rely on spray and/or dipping equipment to deposit a base adhesion film, where a film growth on the surface of the copper is driven by a copper-ligand complexation at the copper surface. This induces a three-dimensional intermolecular polymerization to form the bulk film matrix. At this point, a process flow for wet adhesion promoters uses a wet desmear process post via drilling to clean and mechanically etch dielectrics inside of the via to enable a good adhesion using an electroless seed layer.

However, this first group of implementations start from a tri-functional group-ended monomer in the deposition solution. This involves gathering all functionalities into one molecule structure and limits the flexibility on the molecular design and synthesis, in which case some of the more favorable functional groups with the desired adhesion performance may not be practically utilized. Furthermore, these implementations rely on inter-molecular polymerization and complexation to form the film matrix, which results in highly disordered three-dimensional stack-ups and thus may result in potential film defects and low bonding density. As a result, the overall effective adhesion between copper and dielectric may be compromised. The weak bonding strength and vulnerability from downstream manufacturing processes that include wet desmear chemistry (e.g. a microetch), may cause a wet chemical attack of organic or inorganic adhesive promoters during subsequent processing may result in interface failure and reliability issues.

In a second group of implementations, an inorganic adhesion promoter, for example silicon nitride (SiNₓ) thin film, may be deposited by a plasma enhanced chemical vapor deposition (PECVD) process or by a sputtering process. This may act as a diffusion barrier to prevent oxidation of a copper substrate by forming a bond with the copper. A process flow for dry adhesion promoters may involve dry desmear processes post via drilling to completely remove any dielectric residual in the via without mechanically etching dielectrics inside of a via. Thus, a dry sputter seed layer is required to enable good adhesion to the dielectric surface.

However, the second group of implementations has a high manufacturing process cost and is challenging to use for high-volume manufacturing. In addition, downstream processes after the PECVD or sputtering, for example desmear and seed, are typically dry processes that are plasma based to enable SiNₓ technology. This causes the overall cost of the integrated process to ramp up significantly. As a result, the overall process flow involving SiNₓ deposition, dry etch, and sputtered seed processes is not cost-effective due to, but not limited to, the highly expensive toolsets, limited process throughputs, and underdeveloped tools and processes needed to implement these processes.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

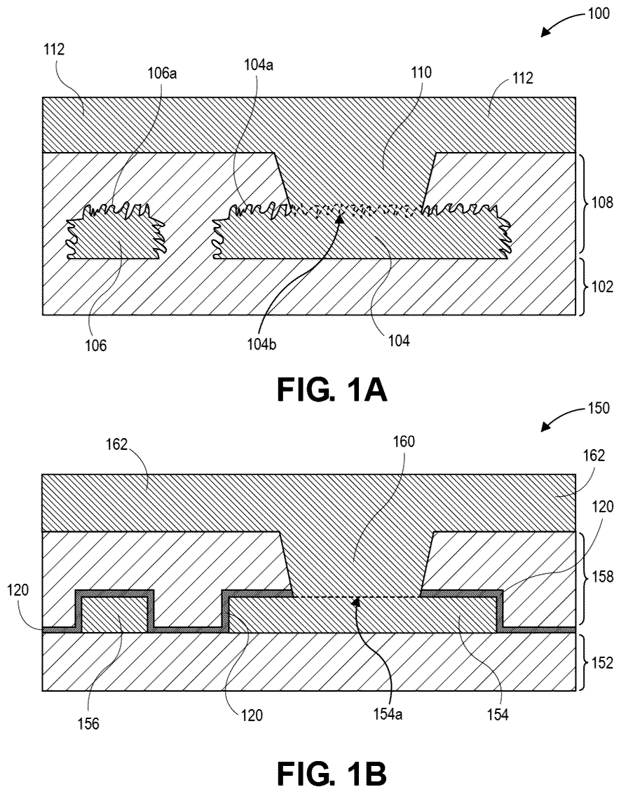

FIGS. 1A-1B illustrate cross section side views of a legacy copper trace with a roughened surface within a substrate and a copper trace with an organic adhesion promoter (OAP) partially surrounding a copper trace within a substrate, in accordance with various embodiments. FIG. 1A shows a cross section side view of a legacy substrate 100 that includes a first dielectric layer 102 onto which a first trace 104 and a second trace 106 are placed. A process, which may include wet chemical etching, is used to create a roughened surface 104a of the first trace 104 and a roughened surface 106a of the second trace 106.

Additional dielectric layers 108 are physically coupled, for example laminated to the roughened surface 104a and the roughened surface 106a. The roughened surfaces promote a solid bond to minimize delamination of the additional dielectric layers 108 from the first trace 104 and the second trace 106.

In legacy implementations, a copper via 110 may be created and electrically coupled with the first trace 104 by removing a portion of the dielectric layers 108 above a roughened surface 104b of the first trace 104, and filling the removed portion with copper. The copper deposited in the copper via 110 is in physical and electrical contact with a portion of the roughened surface 104b of the first trace 104. Additional copper 112 may be deposited on the dielectric layers 108. As a result of the roughened interface, insertion loss may be increased during operation, as is discussed further below.

FIG. 1B shows a cross section side view of an embodiment of a substrate 150 that includes a first dielectric layer 152, which may be similar to the first dielectric layer 102 of FIG. 1A. A first trace 154 and a second trace 156 may be placed on the first dielectric layer 152. Unlike first trace 104 and second trace 106 of FIG. 1B, the first trace 154 and the second trace 156 are not roughened. In embodiments, an OAP layer 120 may be placed on at least a portion of the surfaces of the first trace 154 and the second trace 156. In embodiments, the OAP layer 120 may include an organic-based adhesive film, for example, a saline based self-assembly molecular layer, and the like. In embodiments, the surfaces of the first trace 154 and the second trace 156 are smooth surfaces, or surfaces with low surface roughness. In embodiments, a thickness of the OAP layer 120 may range from a few nanometers to hundreds of micrometers.

In embodiments, additional dielectric layers 158 may be placed, or laminated, on the OAP layer 120 that at least partially covers the first trace 154 and the second trace 156. In embodiments, the OAP layer facilitates bonding between the traces 154, 156 and the dielectric layers 158. In embodiments, a copper via 160 may be placed on the surface 154a of the first trace 154 by removing a portion of the dielectric layers 158. In embodiments, a portion of the OAP layer 120 may be removed prior to deposition of the copper, as described further below, to form the copper via 160. As a result, a physical and electrical interface 154a between the first trace 154 and the copper via 160 is formed that is smooth. As a result of the smooth physical and electrical interface 154a, insertion loss between the copper via 160 and the first trace 154 is reduced. Additional copper 162 may be deposited on the dielectric layers 158.

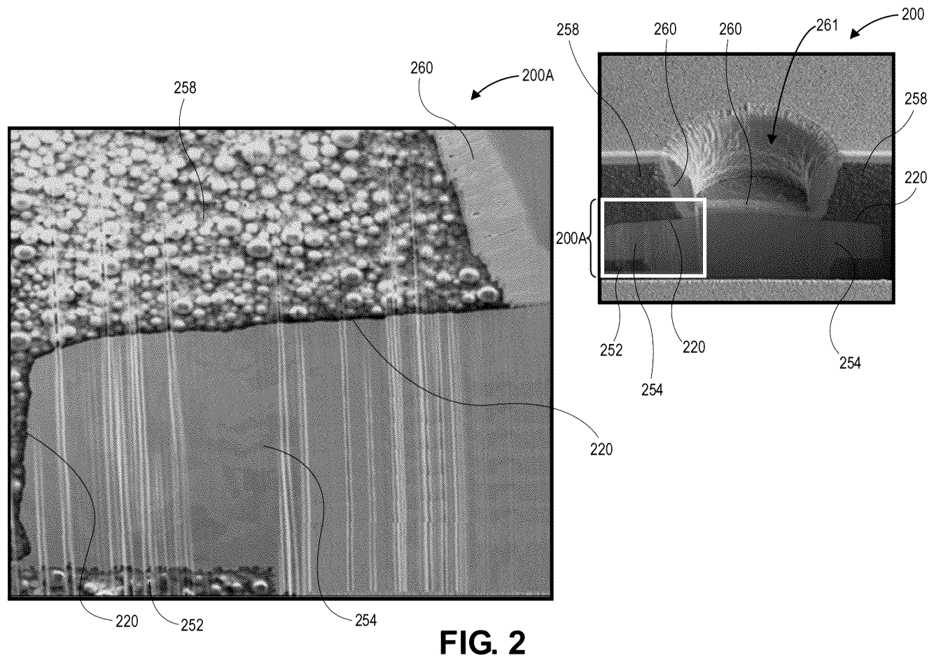

FIG. 2 is a photo of a cross section of a copper trace with an OAP partially surrounding the copper trace with a copper via electrically coupled with the copper trace, in accordance with various embodiments. Illustration 200 is a perspective view of a portion of a substrate, that may be similar to substrate 150 of FIG. 1B, that includes a copper trace 254 that is on a first dielectric layer 252 that is partially surrounded by an OAP layer 220 onto which a copper via 261 is formed and copper seed 260 is placed on a surface of the copper via 261 and on the surface of the trace 254. A second dielectric 258 at least partially surrounds the copper trace 254 and the OAP layer 220. These may be similar to first copper trace 154, first dielectric layer 152, OAP layer 120, portions of copper via 160, and second dielectric layers 158 of FIG. 1B.

Diagram 200A shows a cross-section side view of an enlargement of a portion of illustration 200. As shown, the surface of the copper trace 254 at the OAP layer 220 is smooth, and not rough. In embodiments, the OAP layer may have a roughness that is less than 100 nm. As shown, there is good adhesion between the dielectric layers 258 and the copper trace 254, with no delamination or gap at the interfaces. In embodiments, the copper trace 254 may have a roughness that is less than 100 nm.

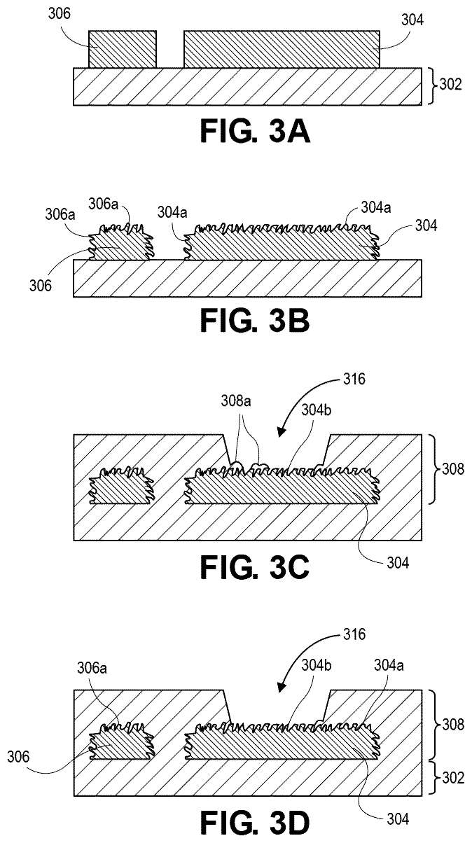

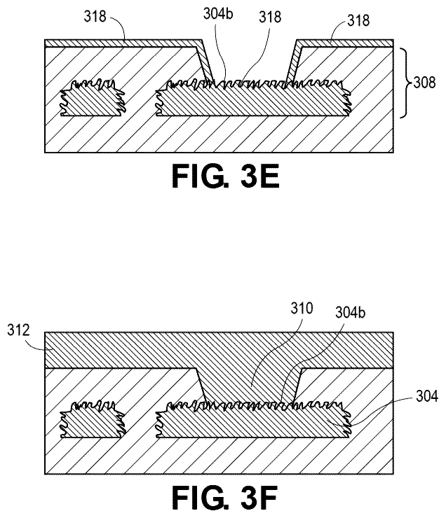

FIGS. 3A-3F illustrate cross section side views of stages in a manufacturing process for creating a legacy substrate that includes copper traces with a roughened surface that are coupled with copper vias. FIG. 3A shows a cross section side view of a stage in a legacy manufacturing process where a first copper trace 304 and a second copper trace 306 are placed on a dielectric layer 302. In embodiments, the dielectric layer 302 may be a dielectric layer within a substrate, or may be a wafer. In embodiments, the first copper trace 304, second copper trace 306, and dielectric layer 302 may be similar to first copper trace 104, second copper trace 106, and dielectric layer 102 of FIG. 1A.

FIG. 3B shows a cross section side view of a stage in a legacy manufacturing process where the surfaces 304a of the first copper trace 304 and the surfaces 306a of the second copper trace 306 are roughened. In implementations, the roughening may be performed using wet chemical etching techniques. The roughened surfaces 304a, 306a, may promote greater dielectric adhesion to portions of the roughened surfaces 304a, 306a as discussed further below.

FIG. 3C shows a cross section side view of a stage in a legacy manufacturing process where a dielectric 308 may be placed, for example using lamination, on the surface of the dielectric layer 302, and also placed on the first trace 304 and the second trace 306. Note that the roughened surfaces 304a, 306a, provide a greater surface area for the dielectric 308 to bond. In implementations, this may reduce the possibility of delamination between the dielectric 308 and the first copper trace 304 or the second copper trace 306.

Subsequently, a drill process, that may include a laser drill, may be used to create a cavity 316 within the dielectric 308 to expose a portion of the roughened surface 304b, which is a portion of roughened surface 304a of FIG. 3B, of the copper trace 304. During this process, there may be dielectric particles 308a on the roughened surface 304b that need to be removed prior to copper seed deposition.

FIG. 3D shows a cross section side view of a stage in a legacy manufacturing process where a wet desmear process may be used to remove the dielectric particles 308a shown in FIG. 3C.

FIG. 3E shows a cross section side view of a stage in the manufacturing process where an electroless (e-less) seed process may be used to deposit a seed layer 318 on the dielectric 308 and on the portion of the roughened surface 304b.

FIG. 3F shows a cross section side view of a stage in a legacy manufacturing process where a copper plating process is performed on top of the seed layer 318 of FIG. 3E, resulting in a copper 310 that at least partially fills the cavity 316 of FIG. 3D and provides an electrical coupling between the copper 310 and the first copper trace 304 using the roughened surface 304b. A copper layer 312 may be above and electrically coupled with the copper 310.

This legacy process that is shown with respect to FIGS. 3A-3E may be referred to as a wet semi additive process flow. If this legacy process is performed where a smooth surface of the copper trace is used, the wet desmear stage as described with respect to FIG. 3D may chemically attack the interface between the dielectric 308 and the smooth surface of the copper trace 304, increasing the likelihood of delamination.

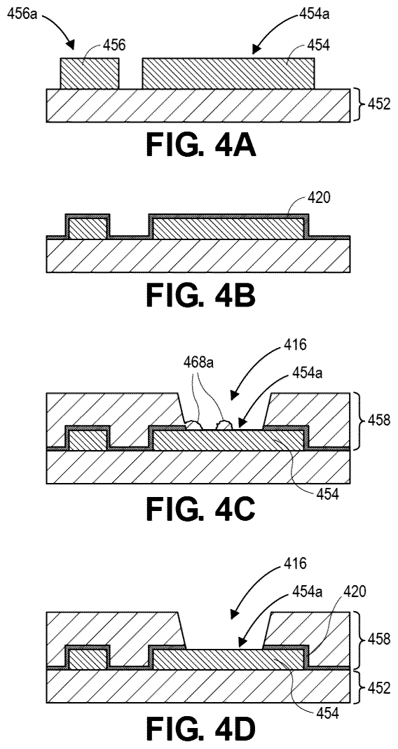

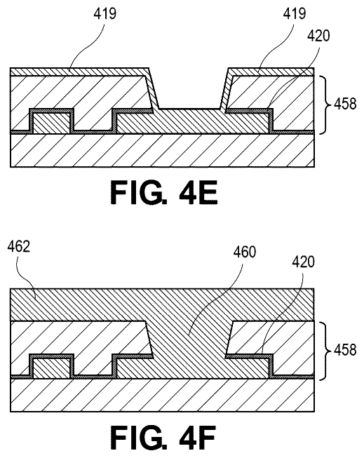

FIGS. 4A-4F illustrate cross section side views of stages in a manufacturing process for creating a substrate that includes copper traces with an OAP partially surrounding the copper traces that are coupled with a copper via, in accordance with various embodiments. FIG. 4A shows a cross section side view of a stage in the manufacturing process where a first copper trace 454 and a second copper trace 456 are placed on a dielectric layer 452. In embodiments, the first copper trace 454, second copper trace 456, and dielectric layer 452 may be similar to first copper trace 154, second copper trace 156, and dielectric layer 152 of FIG. 1B.

In embodiments, the dielectric layer 452 may be a dielectric layer within a substrate, or may be a wafer. Note that the top surface 454a of the first copper trace 454 and the top surface 456a of the second copper trace 456 are smooth. This smoothness may be a result of the legacy deposition techniques for depositing the first copper trace 454 and the second copper trace 456 on the dielectric layer 452. Note that in embodiments, the first copper trace 454 and the second copper trace 456 have not been roughened.

FIG. 4B shows a cross section side view of a stage in the manufacturing process where an OAP layer 420 is applied to the dielectric layer 452, and to the first trace 454 and the second trace 456. In embodiments, the OAP layer 420 may be partially applied to a top surface of the first trace 454 or a top surface of the second trace 456. In embodiments, the OAP layer 420 may be deposited using wet coating or dry lamination techniques. In embodiments, the OAP layer 420 may include materials such as silicon, silicane, a silicane-based self-assembly layer, or an organic-based adhesive. In embodiments the OAP layer 420 may have a thickness that is 500 μm or less. In embodiments, the OAP layer 420 is a non-roughening OAP.

FIG. 4C shows a cross section side view of a stage in the manufacturing process where a dielectric 458 may be placed, for example using lamination, on the OAP layer 420 and/or on a surface of the dielectric layer 452, the first copper trace 454, and the second copper trace 456. In embodiments, the dielectric 458 may be referred to as a build-up dielectric. In embodiments, the OAP layer 420 may reduce the possibility of delamination between the dielectric 458 and the first copper trace 454 or the second copper trace 456.

Subsequently, a drill process, that may include a laser drill, may be used to create a cavity 416 within the dielectric 458 to expose a portion of the surface 454a of the copper trace 454. In embodiments, the laser drill may be a CO₂ or ultraviolet (UV) laser drill. In embodiments, the surface 454a of copper trace 454 may be similar to the surface 154a of the first copper trace 154 of FIG. 1B. During the drill process, there may be residual dielectric particles 468a on the surface 454a on the first copper trace 454 that need to be removed prior to copper seed deposition.

FIG. 4D shows a cross section side view of a stage in the manufacturing process where a dry desmear process is performed to remove the dielectric particles 468a of FIG. 4C. Note that the drill process of FIG. 4C and the desmear process may remove a portion of the OAP layer 420 on the surface 454a of the first trace 454 below cavity 416. In embodiments, this stage may be followed by a water rinsing step for removal of any loosely-bonded particles.

FIG. 4E shows a cross section side view of a stage in the manufacturing process where a sputter seed deposition technique may be used to deposit a seed layer 419 on the dielectric 458, and on the first copper trace 454. Note that FIG. 4E may be a diagram of the structure that is illustrated in FIG. 2, where first copper trace 454, seed layer 419, OAP layer 420, and dielectric 458 may correspond to copper trace 254, seed layer 260, OAP layer 220, and dielectric 258 of FIG. 2.

FIG. 4F shows a cross section side view of a stage in the manufacturing process where a copper plating process is performed on top of the seed layer 419 of FIG. 4E. This plating process may result in a copper layer 460 that is at least partially within the cavity 416, and is electrically coupled with a copper layer 462 on top of the dielectric 458.

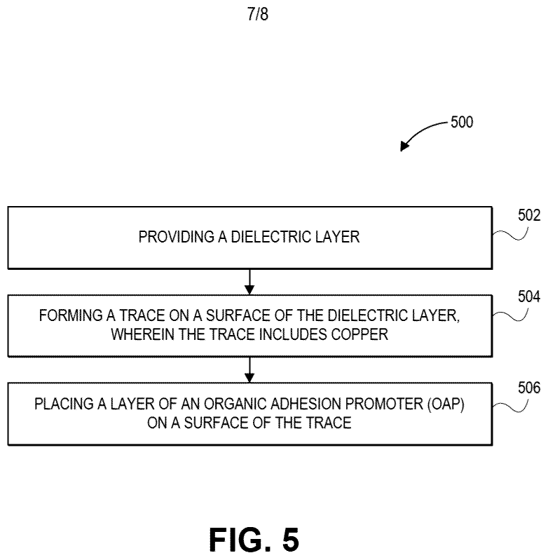

FIG. 5 illustrates an example process for creating a copper trace that is partially surrounded with an OAP and coupled with a copper via, in accordance with various embodiments. In embodiments, the process 500 may be implemented using the apparatus, systems, techniques, and/or processes described herein, and in particular with respect to FIGS. 1A-4F.

At block 502, the process may include providing a dielectric layer. In embodiments, the dielectric layer may be similar to dielectric layer 152 of FIG. 1B or dielectric layer 452 of FIGS. 4A-4F. In embodiments, the dielectric layer may be a dielectric layer within a substrate.

At block 504, the process may further include forming a trace on a surface of the dielectric layer, wherein the trace includes copper. In embodiments, the trace may be similar to first copper trace 154 or second copper trace 156 of FIG. 1B, copper trace 254 of FIG. 2, or first copper trace 454 or second copper trace 456 of FIGS. 4A-4F.

At block 506, the process may further include placing a layer of an organic adhesion promoter (OAP) on a surface of the trace. In embodiments, the OAP may be similar to OAP 220 of FIG. 2, or OAP 420 of FIGS. 4B-4F.

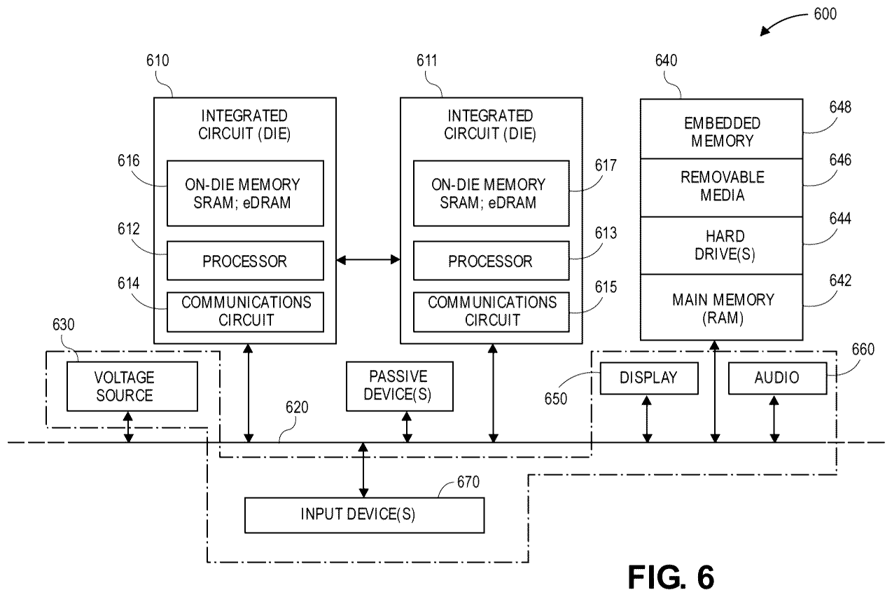

FIG. 6 is a schematic of a computer system 600, in accordance with an embodiment of the present invention. The computer system 600 (also referred to as the electronic system 600) as depicted can embody an organic adhesion promotor for dielectric adhesion to a copper trace, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, an organic adhesion promotor for dielectric adhesion to a copper trace, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 644, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having an organic adhesion promotor for dielectric adhesion to a copper trace, according to any of the several disclosed embodiments and their equivalents, an electronic system, a computer system, one or more methods of fabricating an integrated circuit, and one or more methods of fabricating an electronic assembly that includes a package substrate having an organic adhesion promotor for dielectric adhesion to a copper trace, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having an organic adhesion promotor for dielectric adhesion to a copper trace, embodiments and their equivalents. A foundation substrate may be included, as represented by the dashed line of FIG. 6. Passive devices may also be included, as is also depicted in FIG. 6.

### Examples

The following paragraphs describe examples of various embodiments.

Example 1 is a die comprising: a substrate; a feature that includes copper, wherein the feature has a first side and a second side opposite the first side, wherein the second side of the feature is coupled with the substrate; a layer that includes an organic adhesion promoter (OAP) on at least a portion of the first side of the feature; and a layer that includes a dielectric on the layer that includes the OAP.

Example 2 includes the die of example 1, or of any other example or embodiment herein, wherein the OAP includes a selected one or more of: silicon, silicane, a silicane-based self-assembly layer, or an organic-based adhesive.

Example 3 includes the die of example 1, or of any other example or embodiment herein, wherein a surface of the first side of the feature has a roughness that is less than 100 nm.

Example 4 includes the die of example 1, or of any other example or embodiment herein, wherein the feature that includes copper is a copper trace.

Example 5 includes the die of example 1, or of any other example or embodiment herein, wherein the OAP is on a first portion of the first side of the feature, and wherein the OAP is not on a second portion of the first side of the feature.

Example 6 includes the die of example 5, or of any other example or embodiment herein, further comprising copper on the second portion of the first side of the feature.

Example 7 includes the die of example 6, or of any other example or embodiment herein, wherein the copper on the second portion of the first side of the feature includes a copper seed.

Example 8 includes the die of example 1, or of any other example or embodiment herein, wherein the first side of the feature, the OAP on the first side of the feature, and the layer that includes a dielectric on the OAP form a continuous layer.

Example 9 includes the die of example 1, or of any other example or embodiment herein, wherein the substrate includes a dielectric material.

Example 10 includes the die of example 1, or of any other example or embodiment herein, wherein the layer that includes the OAP has a thickness between 2 nm and 200 μm.

Example 11 is a package comprising: a die; and a substrate electrically coupled with the die, the substrate comprising: a first dielectric layer; a trace that includes copper on the first dielectric layer; a layer that includes an organic adhesion promoter (OAP) on a first portion of a surface of the trace; and a second dielectric layer on the layer that includes the OAP on the first portion of the surface of the trace.

Example 12 includes the package of example 11, or of any other example or embodiment herein, wherein the OAP includes a selected one or more of: silicon, silicane, a silicane-based self-assembly layer, or an organic-based adhesive.

Example 13 includes the package of example 11, or of any other example or embodiment herein, wherein the trace further includes a second portion of the surface of the trace that does not include an OAP on the second portion of the surface of the trace.

Example 14 includes the package of example 13, or of any other example or embodiment herein, further including an electrically conductive material on the second portion of the surface of the trace.

Example 15 includes the package of example 14, or of any other example or embodiment herein, wherein the electrically conductive material includes copper.

Example 16 includes the package of example 14, or of any other example or embodiment herein, wherein the electrically conductive material includes copper seed.

Example 17 includes the package of example 11, or of any other example or embodiment herein, further including OAP on an edge of the trace between the surface of the trace and the surface of the first dielectric layer.

Example 18 includes the package of example 11, or of any other example or embodiment herein, wherein the surface of the trace has a roughness that is less than 100 nm.

Example 19 is a method comprising: providing a dielectric layer; forming a trace on a surface of the dielectric layer, wherein the trace includes copper; and placing a layer of an organic adhesion promoter (OAP) on a surface of the trace.

Example 20 includes the method of example 19, or of any other example or embodiment herein, wherein the OAP includes a selected one or more of: silicon, silicane, a silicane-based self-assembly layer, or an organic-based adhesive.

Example 21 includes the method of example 19, or of any other example or embodiment herein, wherein a thickness of the layer of OAP is less than 200 μm.

Example 22 includes the method of example 19, or of any other example or embodiment herein, wherein the dielectric layer is a first dielectric layer; and further comprising forming a second dielectric layer on the layer of the OAP on the surface of the trace.

Example 23 includes the method of example 22, or of any other example or embodiment herein, further comprising: removing a portion of the layer of the OAP and a portion of the second dielectric layer above the portion of the layer of the OAP; and placing a material that includes copper within the removed portion of the layer of the OAP and the removed portion of the second dielectric layer, wherein the material that includes copper is electrically coupled with the trace.

Example 24 includes the method of example 23, or of any other example or embodiment herein, wherein removing the portion of the layer of the OAP and the portion of the second dielectric layer above the portion of the layer of the OAP further includes: drilling the portion of the second dielectric layer above the portion of the layer of the OAP; exposing a portion of a surface of the trace by removing the portion of the layer of the OAP using a dry desmear process; and sputtering a copper seed onto the exposed portion of the surface of the trace.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A die comprising:
a substrate;
a feature that includes copper, wherein the feature has a first side and a second side opposite the first side, wherein the second side of the feature is coupled with the substrate;
a layer that includes an organic adhesion promoter (OAP) on at least a portion of the first side of the feature; and
a layer that includes a dielectric on the layer that includes the OAP.

2. The die of claim 1, wherein the OAP includes a selected one or more of: silicon, silicane, a silicane-based self-assembly layer, or an organic-based adhesive.

3. The die of claim 1, wherein a surface of the first side of the feature has a roughness that is less than 100 nm.

4. The die of claim 1, wherein the feature that includes copper is a copper trace.

5. The die of claim 1, wherein the OAP is on a first portion of the first side of the feature, and wherein the OAP is not on a second portion of the first side of the feature.

6. The die of claim 5, further comprising copper on the second portion of the first side of the feature.

7. The die of claim 6, wherein the copper on the second portion of the first side of the feature includes a copper seed.

8. The die of claim 1, wherein the first side of the feature, the OAP on the first side of the feature, and the layer that includes a dielectric on the OAP form a continuous layer.

9. The die of claim 1, wherein the substrate includes a dielectric material.

10. The die of claim 1, wherein the layer that includes the OAP has a thickness between 2 nm and 200 μm.

11. A package comprising:
a die; and
a substrate electrically coupled with the die, the substrate comprising:
a first dielectric layer;
a trace that includes copper on the first dielectric layer;
a layer that includes an organic adhesion promoter (OAP) on a first portion of a surface of the trace; and
a second dielectric layer on the layer that includes the OAP on the first portion of the surface of the trace.

12. The package of claim 11, wherein the OAP includes a selected one or more of: silicon, silicane, a silicane-based self-assembly layer, or an organic-based adhesive.

13. The package of claim 11, wherein the trace further includes a second portion of the surface of the trace that does not include an OAP on the second portion of the surface of the trace.

14. The package of claim 13, further including an electrically conductive material on the second portion of the surface of the trace.

15. The package of claim 14, wherein the electrically conductive material includes copper.

16. The package of claim 14, wherein the electrically conductive material includes copper seed.

17. The package of claim 11, further including OAP on an edge of the trace between the surface of the trace and the surface of the first dielectric layer.

18. The package of claim 11, wherein the surface of the trace has a roughness that is less than 100 nm.

19. A method comprising:
providing a dielectric layer;
forming a trace on a surface of the dielectric layer, wherein the trace includes copper; and
placing a layer of an organic adhesion promoter (OAP) on a surface of the trace.

20. The method of claim 19, wherein the OAP includes a selected one or more of: silicon, silicane, a silicane-based self-assembly layer, or an organic-based adhesive.

21. The method of claim 19, wherein a thickness of the layer of OAP is less than 200 μm.

22. The method of claim 19, wherein the dielectric layer is a first dielectric layer; and further comprising forming a second dielectric layer on the layer of the OAP on the surface of the trace.

23. The method of claim 22, further comprising:
removing a portion of the layer of the OAP and a portion of the second dielectric layer above the portion of the layer of the OAP; and
placing a material that includes copper within the removed portion of the layer of the OAP and the removed portion of the second dielectric layer, wherein the material that includes copper is electrically coupled with the trace.

24. The method of claim 23, wherein removing the portion of the layer of the OAP and the portion of the second dielectric layer above the portion of the layer of the OAP further includes:
drilling the portion of the second dielectric layer above the portion of the layer of the OAP;
exposing a portion of a surface of the trace by removing the portion of the layer of the OAP using a dry desmear process; and
sputtering a copper seed onto the exposed portion of the surface of the trace.
